(19) United States
(12) Patent Application Publication
(10) Pub. No.: US 2013/0040047 A1
(43) Pub. Date: Feb. 14, 2013

(54) METHOD FOR MANUFACTURING EL DEVICE

(71) Applicant: Tetsuya Karaki, Kawasaki-shi (JP)

(72) Inventor: Tetsuya Karaki, Kawasaki-shi (JP)

(73) Assignee: CANON KABUSHIKI KAISHA, Tokyo (JP)

(21) Appl. No.: 13/568,816

(22) Filed: Aug. 7, 2012

(30) Foreign Application Priority Data
Aug. 11, 2011 (JP) 2011-175899

(51) Int. Cl. H05B 33/10; C23C 16/04

(52) U.S. Cl. 427/66; 118/720

(57) ABSTRACT

Provided is a method for manufacturing an EL device formed in each of a plurality of sections arrayed in matrix form on a substrate, the method including the step of depositing an evaporant onto the substrate through a mask held between the substrate and an evaporation source opposite the substrate, the mask having deposition patterns of all the sections in a column direction as openings, wherein the step is repeated while moving the substrate in a row direction of the sections one column at a time.

### BACKGROUND OF THE INVENTION

1. Field of the Invention

The present invention relates to a method for manufacturing an EL device, and in particular, to a method and apparatus for vapor deposition for use in the process of manufacturing an EL device.

2. Description of the Related Art

Organic EL display devices have recently begun to be mounted in mobile phones and so on having various functions. The organic EL display devices have the advantages of high image quality, capability of movie display, low power consumption, etc. and thus have begun to be used also in television systems, digital cameras, in-car displays, and so on, as well as the mobile phones.

The organic EL display devices are manufactured in such a manner that a thin film transistor (TFT) array is formed on a glass substrate, as are liquid-crystal display devices, on which a pixel electrode and an organic film serving as a light emitting layer are deposited. The organic film is generally formed by vacuum deposition. To manufacture a color display device, red, green, and blue organic luminescent materials are vacuum-deposited on the respective pixel positions through a mask having openings.

The resolutions of displays are increasingly becoming finer, and 3-inch VGA displays are coming into use. In this case, the pixel pitch is about 100 μm. Thus, the accuracy of the size and pitch of the openings of a mask for vacuum deposition is set to be extremely high.

In vapor deposition, the substrate and the mask are placed in close contact or in close vicinity at a distance sufficiently smaller than the size of the openings. A long distance between the substrate and the mask causes an evaporant to come around the rims of the mask openings and are deposited thereon, thus damaging the sharpness of the edge of the deposition pattern. This also causes color mixture between adjacent pixels.

Since the mask is formed of thin metal foil having a thickness of 100 μm or less to obtain an accurate deposition pattern, distortion is prone to occur when it is held in close vicinity of the substrate. Furthermore, the mask is prone to expand and to be deformed due to radiant heat generated from an evaporation source. The distortion and deformation cause the position of the openings of the mask to shift or the shapes thereof to be deformed, thus decreasing the accuracy of vapor deposition.

The mask is generally fixed to a frame (frame member) and is held by application of tension to eliminate the distortion and deformation. Japanese Patent Laid-Open No. 2003-068453 discloses that application of tension along the longitudinal direction of slit-shaped openings allows the position and shape of the openings to be maintained, thus increasing the accuracy of the deposition pattern.

The size of the glass substrate is becoming larger in view of improvement of production efficiency; for example, large substrates having a G4Q size (365 mm×460 mm), a G3 size (550×670 mm), and a G4 size (730×920 mm) are used. However, increasing the mask size to suit such large substrates decreases the accuracy of the opening pitch. Furthermore, it is difficult to bring the mask into uniformly close contact with or vicinity to the substrate.

Japanese Patent Laid-Open No. 2010-116591 discloses a method of vapor deposition, with the deposition region of a large substrate divided into a plurality of sections. Vapor deposition is repeated using a mask smaller than the substrate every time the substrate is moved stepwise. However, the method of vapor deposition, with the deposition region of the large substrate divided into a plurality of sections, performs the vapor deposition on each of the divided sections, thus taking much time to perform vapor deposition.

Furthermore, the mask is placed in close contact with or close vicinity to the lower surface of the substrate because vapor deposition is generally performed from the substrate that is placed horizontally. Thus, a large substrate deflects when held horizontally, and thus, performing vapor deposition on the individual divided sections causes the distance between the substrate and the mask to change depending on the deposition position, thus making it difficult to perform uniform vapor deposition across the entire substrate.

### SUMMARY OF THE INVENTION

The present invention provides a method for manufacturing an EL device formed in each of a plurality of sections arrayed in matrix form on a substrate, the method comprising the step of depositing an evaporant onto the substrate through a mask held between the substrate and an evaporation source opposite the substrate, the mask having deposition patterns of all the sections in a column direction as openings, wherein the step is repeated while moving the substrate in a row direction of the sections one column at a time.

The present invention provides a vapor deposition method for forming deposition patterns in individual plurality of sections arrayed in matrix form on a substrate, the method comprising the step of depositing an evaporant onto the substrate through a mask held between the substrate and an evaporation source opposite the substrate, the mask having deposition patterns of all the sections in a column direction as openings, wherein the step is repeated while moving the substrate in a row direction of the sections one column at a time.

The present invention provides a vapor deposition apparatus comprising an evaporation source; a rectangular mask; a mask frame that fixes the short sides of the rectangular mask and that holds the rectangular mask by applying a tension in a longitudinal direction; a substrate supporting unit provided along the extensions of the two short sides of the rectangular mask and supporting a substrate whose length is larger than the short sides of the rectangular mask with opposing two sides of the substrate supporting unit; a moving mechanism that moves the substrate supporting unit in the lengthwise direction of the substrate by a predetermined distance; and an alignment unit that adjusts the relative position of the rectangular mask and the substrate.

According to an embodiment of the present invention, deposition patterns can be formed with high accuracy in a short time also for a large substrate.

Further features of the present invention will become apparent from the following description of exemplary embodiments with reference to the attached drawings.

### BRIEF DESCRIPTION OF THE DRAWINGS

FIG. 1 is a diagram illustrating a vapor deposition process in an EL device manufacturing process according to an embodiment of the present invention.

FIG. 2 is a diagram illustrating an organic EL display device formed in each section.

FIG. 3 is a diagram illustrating vapor deposition sections on a substrate.

FIG. 4 is a diagram illustrating the shape and arrangement of openings of a mask.

FIG. 5 is a diagram illustrating a mask frame.

FIG. 6 is a diagram illustrating the configuration of an alignment unit.

FIG. 7 is a diagram illustrating the configuration of a substrate supporting unit and a method for moving the substrate.

FIGS. 8A to 8E are diagrams illustrating a vapor deposition process for individual columns.

FIG. 9 is a diagram illustrating batch vapor deposition of the entire surface.

FIG. 10 is a diagram illustrating the measurement results of film thickness distribution.

FIG. 11 is a diagram illustrating a configuration in which a plurality of evaporation sources are arranged.

### DESCRIPTION OF THE EMBODIMENTS

A method for manufacturing an EL device according to embodiments of the present invention will be described with reference to the drawings. Although a description is made taking an organic EL display device as an example, the present invention can be applied to all light emitting devices using organic EL or inorganic EL, such as an EL display device and an illuminating unit that use inorganic EL.

Well-known or known techniques are applied to components that are not particularly illustrated or described in this specification. The embodiment described below is merely an embodiment of the present invention, and the invention is not limited thereto.

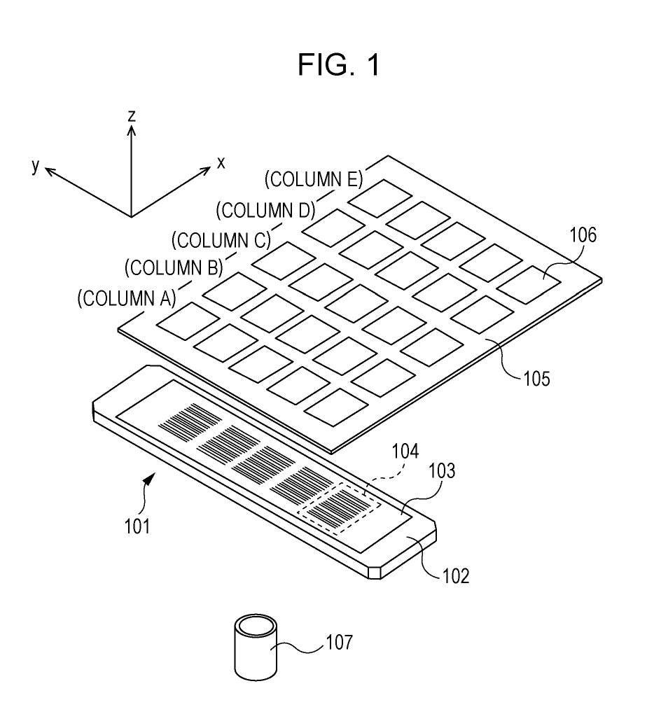

FIG. 1 illustrates a vapor deposition process in an EL device manufacturing process of the present invention. An evaporant, such as an organic compound that is heated into steam, is discharged from an evaporation source 107 and adheres to a glass substrate 105 through the openings of a mask 103. The evaporant that has adhered is deposited on the glass substrate 105 to form a film of the organic compound or the like.

Organic luminescent layers with the same pattern are deposited on individual sections 106, arrayed in matrix form, of a single glass substrate 105 to form a plurality of organic EL display devices on the glass substrate 105 in a lump. After a one-color organic luminescent layer is deposited on a single substrate, an another-color organic EL layer is deposited on the same glass substrate by a vapor deposition method, and thus a color organic EL display device can be manufactured. After vapor deposition of all colors has finished, the glass substrate 105 is cut off into the sections 106, each of which serves as one organic EL display device.

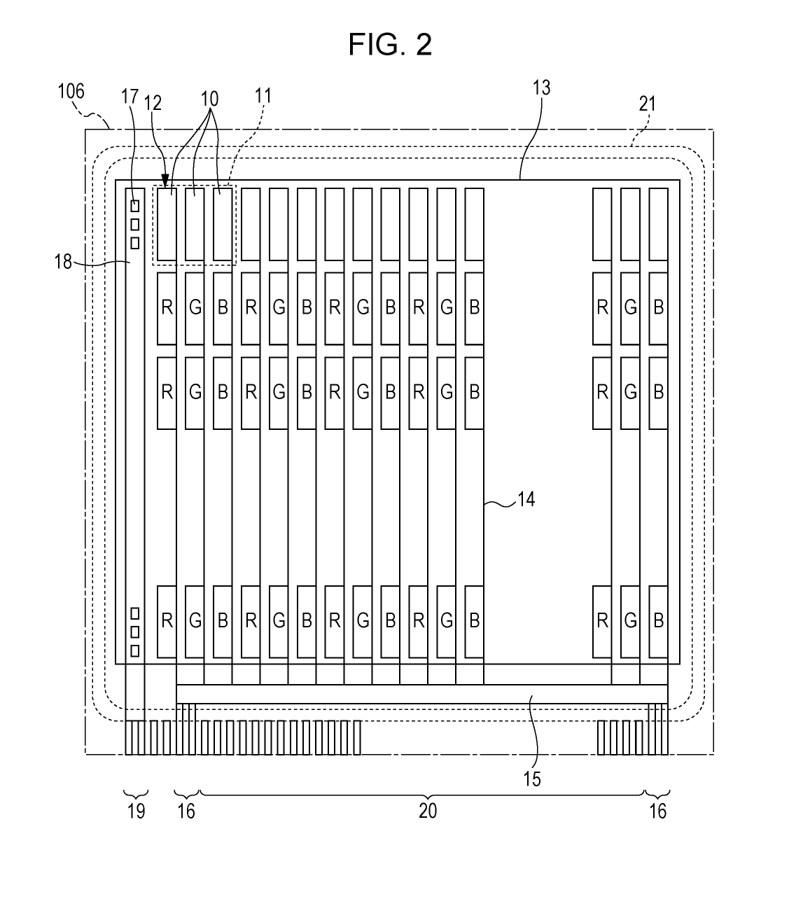

FIG. 2 illustrates the color organic EL display device formed in each section 106.

The color organic EL display device includes pixels 11 formed of RGB-color organic EL elements 10 arrayed in matrix form. The individual organic EL elements 10 are configured such that an organic luminescent substance (not shown) is sandwiched between patterned anode electrodes 12 and a cathode electrode 13 common to all the pixels.

The anode electrodes 12 are connected to a pixel circuit (not shown). The pixel circuit is connected to power supply wires 14 extending in the column direction and is supplied with power supply voltage. The power supply wires 14 becomes a common power supply line 15 outside the pixel array region, through which the anode electrodes 12 are connected to terminals 16. The cathode electrode 13 becomes a cathode power supply line 18 outside the pixel array region through contact portions 17, through which the cathode electrode 13 is connected to terminals 19.

The entire display device other than the terminals 16 and 19 is covered with a sealing can (not shown) that is bonded to the glass substrate 105 with a sealing portion 21 (a portion enclosed by two broken lines), thus being isolated from the outside air.

In addition, although a control circuit for controlling the pixel circuit and a signal generation circuit that sends image signals to the pixel circuit are provided around the array of the pixels 11, they are omitted in FIG. 2. The control circuit and the signal generation circuit receive inputs of control signals and image signals from the outside through terminals 20.

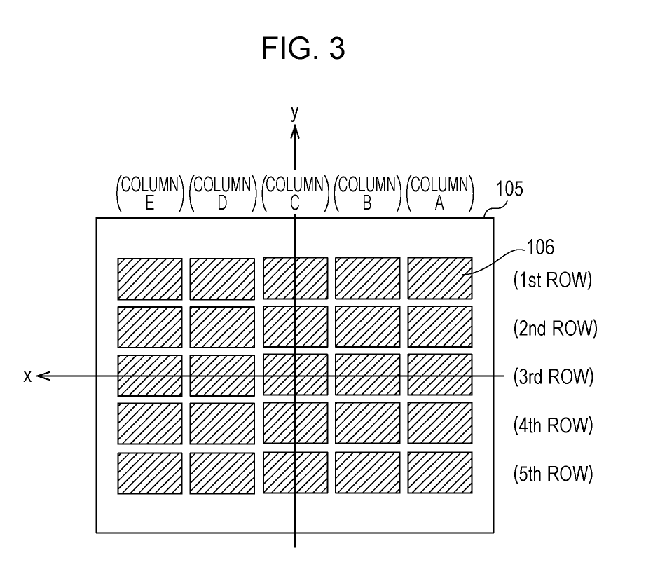

FIG. 3 illustrates the arrangement of deposition regions on the glass substrate 105. The same components as those in FIG. 1 are given the same reference numerals. This also applies to the drawings below.

The glass substrate 105 has 25 sections 106 in total in the first to fifth rows and in columns A to E. FIG. 3 is a diagram of the glass substrate 105 as viewed from a deposition surface. In FIG. 1, the deposition surface is placed downs. The sections 106 are each provided with a driving circuit for the display device and one electrode of the organic EL element 10.

In the process of vapor deposition, one column of the 5×5 sections 106 is deposited in a lump. The vapor deposition is performed from column A to column E one column at a time while the glass substrate 105 and the mask 103 are relatively moved. Thus, deposition patterns are formed in the individual sections 106.

The direction along the row (also referred to as a row direction) of the sections 106 is referred to as an x-axis, the direction along the column (also referred to as a column direction) is referred to as a y-axis, and the direction of the normal of the glass substrate 105 is referred to as a z-axis. A direction in which the glass substrate 105 moves is negative on the x-axis.

The deposition patterns are determined by the mask 103. The mask 103 is a rectangle having substantially the same size as that of one column of the glass substrate 105, whose long side has substantially the same length as that of the column and whose short side has substantially the same width as that of the column. The mask 103 is provided with one column of opening regions 104 corresponding to the deposition patterns of the sections 106.

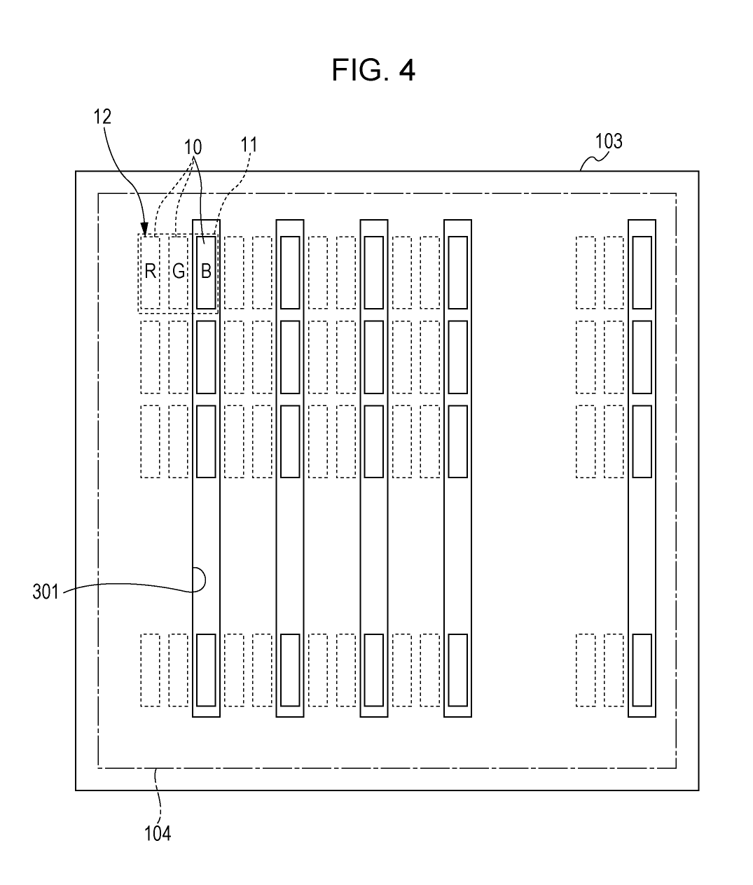

FIG. 4 is an enlarged view of the mask 103 in a single opening region 104.

The mask 103 has openings 301 along one column. The openings 301 correspond to the position of blue (B) organic EL elements 10B of RGB colors and each have a thin long slit shape extending in the column direction. A blue (B)) organic luminescent substance is deposited by using the mask 103 in FIG. 4. Masks for depositing red (R) and green (G)) organic luminescent substances also have similar openings corresponding to respective organic EL elements 10R and 10G.

The opening region 104 corresponds to the deposition pattern of one of the sections 106 of the glass substrate 105. The mask 103 in FIG. 1 has five opening regions 104 in FIG. 4 arranged in the vertical direction. The mask 103 has all of the deposition patterns of one column of the sections 106, so that one column can be deposited in a lump.

The openings 301 are slits that are long and thin in the y-direction. The same number of openings 301 as that of the columns of the pixels of the display device are provided in parallel. The individual slits form stripe deposition patterns on the glass substrate 105.

The mask 103 is an invar plate having a thickness of 40 μm, in which 40-μm slits are formed by etching at a pitch of 120 μm. Any thin metal plate that can be micromachined can be employed; however, a material having a low thermal expansion coefficient is employed to prevent deformation of the mask 103 due to thermal expansion caused by an increase in the temperature of the mask 103 during vapor deposition.

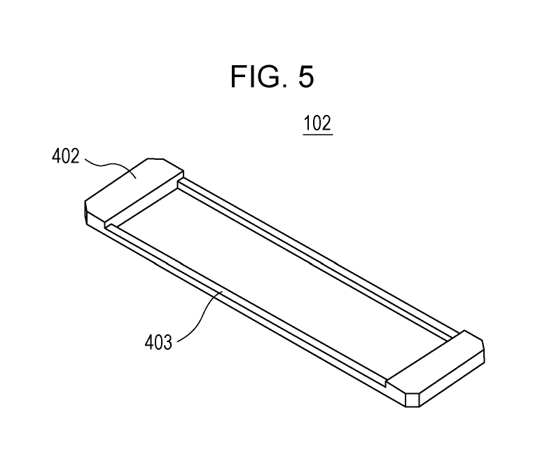

The mask 103 is fixed to a mask frame 102. FIG. 5 illustrates the mask frame 102 in detail. The mask 103 and the mask frame 102 are hereinafter referred to as a mask assembly 101.

The ribs 403 at the long side of the mask frame 102 is set to be smaller in height than ribs 402 at the short side to prevent the ribs 403 from coming into contact with the glass substrate 105 in consideration of the amount of deflection of the mask 103 and the amount of deflection when the glass substrate 105 is placed on the mask 103. The material of the mask frame 102 can be metal, such as steel use stainless (SUS). The mask frame 102 is formed of a material having a low thermal expansion coefficient, like the mask 103, to prevent deformation due to thermal expansion caused by an increase in the temperature of the mask 103 during vapor deposition. In this embodiment, the mask frame 102 is formed of an invar material.

During vapor deposition, the glass substrate 105 is placed in close contact with the mask 103 fixed to the mask frame 102. The evaporation source 107 is disposed at a position opposite to the glass substrate 105 with respect to the mask 103. The number of the evaporation source 107 is not limited to one; it can be increased depending on the length of the deposition region in the Y-direction. FIG. 1 illustrates the mask 103 and the glass substrate 105 spaced apart longer than an actual distance for the purpose of simplification and illustration.

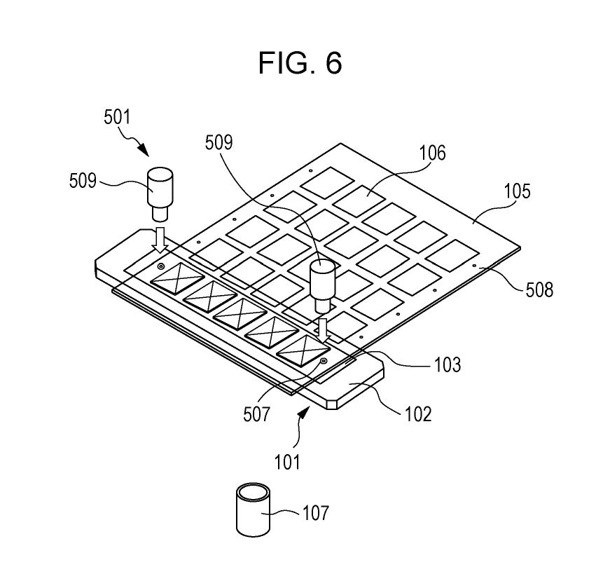

FIG. 6 illustrates an alignment unit 501 that adjusts the relative position of the mask 103 and the glass substrate 105 and a method for aligning them to predetermined positions.

The alignment unit 501 includes an alignment stage (not shown) on which two CCD cameras 509 and the mask 103 are mounted and which moves the mask 103 relative to the glass substrate 105 by a very small distance and a control mechanism (not shown) that analyzes images of the CCD cameras 509 and moves the alignment stage.

The mask 103 and the glass substrate 105 are provided with alignment marks 507 and 508, respectively, for positioning the deposition patterns. The CCD cameras 509 are disposed at two locations to measure the alignment marks 507 provided at the two ends of the mask 103.

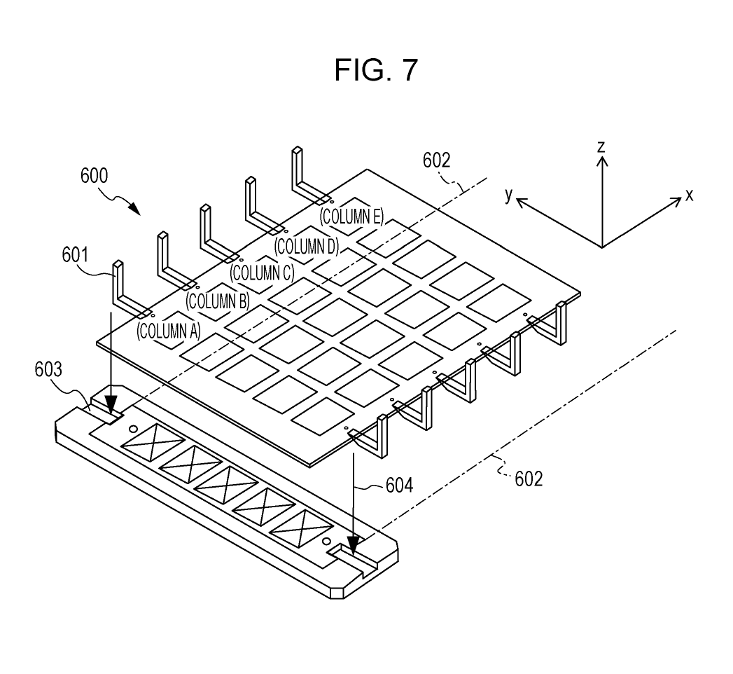

FIG. 7 illustrates a substrate supporting unit 600 and a method for moving the glass substrate 105 stepwise.

The substrate supporting unit 600 includes ten L-shaped support members 601 opposed five members each. The glass substrate 105 is supported horizontally at two sides by the support members 601. The support members 601 are disposed at at least two locations of each side along a line 602 extending from both ends of the mask 103 parallel to the short sides of the mask 103, that is, in the x-direction, to support the two opposing sides of the glass substrate 105. This allows the glass substrate 105 whose length in the x-direction is longer than the short sides of the mask 103 to be supported. Although the glass substrate 105 is supported at the ends of the two sides parallel to the x-axis by the support members 601, the sides parallel to the y-axis are not supported.

The support members 601 can be moved rearwards (in the negative direction on the x-axis) of the mask 103, as well as forwards (in the positive direction on the x-axis). Also at the rear, the support members 601 are similarly located along the lines 602 extending from the ends of the mask 103. The support members 601 move in the direction parallel to the support sides (in the direction of the x-axis) stepwise by a predetermined distance with a moving mechanism (not shown) while the whole support members 601 support the glass substrate 105. This allows the glass substrate 105 to move in the row direction.

The moving mechanism is a well-known mechanism that joins the support members 601 with a single arm and moves them together. Since the movement is limited to the x-direction, the moving mechanism can be simple.

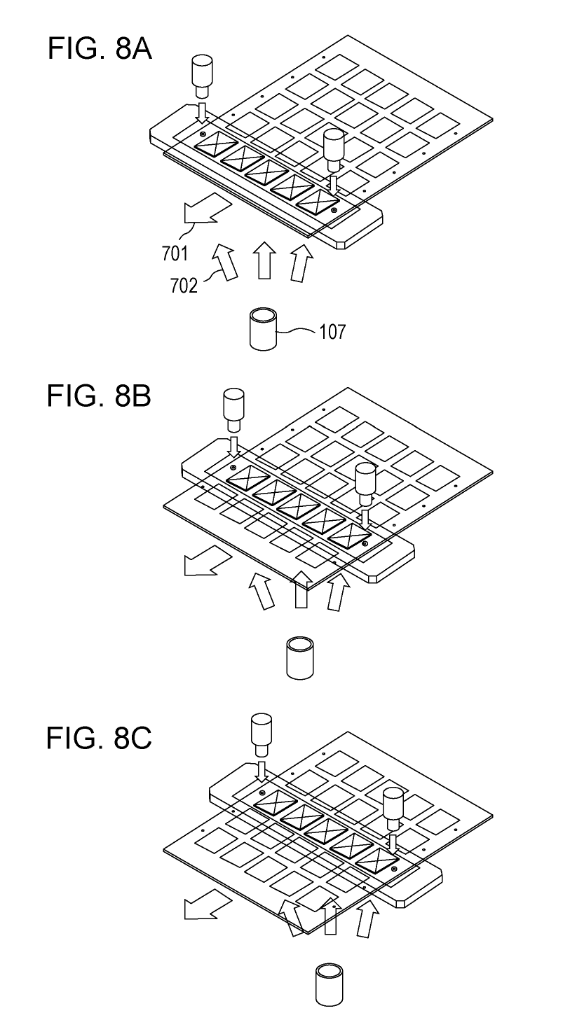

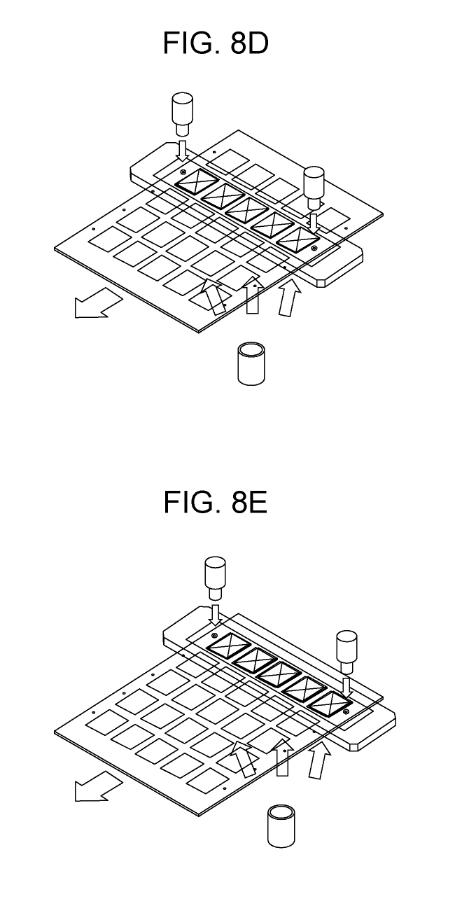

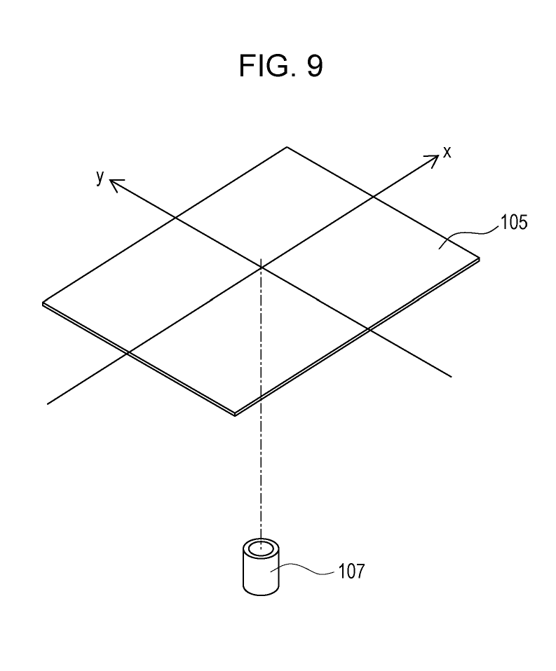

FIGS. 8A to 8E illustrate the step of vapor deposition of the individual columns of the glass substrate 105 supported by the support members 601 in FIG. 7. FIGS. 8A to 8E are vapor deposition process for columns A to E, respectively.

When the glass substrate 105 is conveyed into a vapor deposition chamber, the glass substrate 105 is passed to the support members 601. The support members 601 first move column A of the glass substrate 105 to the position of the mask 103, as shown in FIG. 8A.

In this state, the glass substrate 105 and the mask 103 are aligned with each other. Specifically, the CCD cameras 509 measure the positions of the alignment marks 507 of the mask 103 and the alignment marks 508 of the glass substrate 105. The positions of the alignment marks 507 and 508 are aligned by controlling the alignment stage on which the mask assembly 101 is mounted.

After completion of the aligning, all of the support members 601 move downwards to move the glass substrate 105 downwards to bring the glass substrate 105 and the mask 103 into contact with each other. The support members 601 directly above the mask 103 fall into depressions 603 in the mask frame 102, as indicated by arrows 604, to separate from the glass substrate 105. However, the glass substrate 105 remains supported by the other support members 601.

Since the evaporation source 107 contains an evaporant 702 and discharges the evaporant 702 through an opening, which is normally provided at the upper part, the glass substrate 105 has to be held, with the vapor deposition surface down. Thus, the glass substrate 105 is supported at the edge and deflects vertically downwards at the center. If the glass substrate 105 is large, the deflection is significantly large, and when it is repeatedly subjected to vapor deposition using a mask 103 smaller than the glass substrate 105, it is extremely difficult to bring the mask 103 into close contact with the glass substrate 105 depending on the location of the glass substrate 105.

When the glass substrate 105 is supported horizontally at the edges of the opposing two sides with the support members 601, as shown in FIG. 7, the glass substrate 105 deflects in the direction perpendicular to the two sides, that is, along the y-axis. This deflection is uniform in the direction of the x-axis.

Since the mask 103 is merely fixed to the mask frame 102 at the two sides parallel to the x-axis, the mask 103 readily deflects and deforms in the y-z plane. Accordingly, the mask 103 deforms following the glass substrate 105 merely by placing the glass substrate 105 on the mask 103, thus allowing the glass substrate 105 and the mask 103 to come into close contact with each other across the entire width of the mask 103. Also when the glass substrate 105 and the mask 103 are not to be brought into contact, the whole of the mask 103 can be brought into close vicinity of the glass substrate 105 at a substantially uniform distance by adjusting a tension in the y-direction to be applied to the mask 103 because the glass substrate 105 and the mask 103 are supported in the same direction along the two sides.

After the glass substrate 105 is brought into close vicinity to or close contact with the mask 103, an evaporation source shutter (not shown) of the evaporation source 107 is opened to discharge the evaporant 702 onto the glass substrate 105, and thus vapor deposition of column A is performed. When observation with a film thickness monitor (not shown) shows that the film thickness has reached a predetermined value, the vapor deposition is stopped. Upon completion of the vapor deposition of column A, the support members 601 move upwards to separate the glass substrate 105 from the mask 103, thus returning it to the alignment position. Furthermore, the entire support members 601 move in the direction of arrow 701 to the adjacent support members 601 and align the glass substrate 105 with the position of column B, as shown in FIG. 8B. Alignment of column B is performed as for column A, and vapor deposition is performed.

After the glass substrate 105 is moved successively, vapor deposition of columns C, D, and E is performed for the arrangement in FIGS. 8C, 8D, and 8E. The support members 601 in FIG. 7 are provided one at each end of each column, and the moving distance at one time is equal to the distance between the support members 601 in the x-direction.

The manufacturing method according to an embodiment of the present invention performs vapor deposition on one column at a time by using the mask 103 having openings corresponding to all the deposition patterns corresponding to one column of the glass substrate 105. The glass substrate 105 is conveyed stepwise in the direction of the x-axis because the support members 601 fall into the depressions 603 of the mask frame 102, and every time it is aligned with the mask 103, where vapor deposition is performed.

Since it is sufficient to move the glass substrate 105 only in one direction, the moving mechanism can be simplified. Since one column is subjected to vapor deposition at a time, it is sufficient to repeat the vapor deposition by the number of columns, and hence shorter time is required than that of a method of vapor deposition of one section to another. Furthermore, since the glass substrate 105 and the mask 103 are fixed along the two sides in the same direction, the shapes of the deflections are the same, thus allowing the wholes to be uniformly brought into close contact with each other.

The present invention will be specifically described using examples.

### EXAMPLE 1

An organic EL layer was deposited on a G4Q glass substrate 105 (a width of 365 mm along the y-axis x a length of 460 mm along the x-axis) with the vapor deposition apparatus with the configuration in FIG. 1.

The mask 103 is an invar thin plate with a thickness of 40 μm processed into a rectangle having a short side of 90 mm and a long side of 440 m, in which five opening regions 104 corresponding to the sections 106 of the glass substrate 105 are formed. The opening regions 104 each have slits having a width of 40 μm parallel to the long side at a pitch of 120 μm.

The mask 103 is fixed to the mask frame 102 in FIG. 5, in a state in which a tension of 6.0±0.1 kgf is applied to both short sides. Since the direction of the tension is the same as that of the slits, the tension of the mask 103 is kept uniform at individual portions, thus increasing the accuracy of the positions and shapes of the openings.

Increasing the mask size to suit a large glass substrate makes it difficult to maintain high accuracy. Even with a high-accuracy mask having the same size as the glass substrate 105, it is difficult to maintain the high accuracy by applying a uniform tension thereto. A small distortion that has occurred when the mask 103 is fixed to the support frame 102 is increased due to a slight distortion of the support frame 102 that has occurred when a tension is applied thereto, thus inevitably causing unevenness in tension. This also applies to a case where a tension in the longitudinal direction of the slits is applied to the mask 103 having slit openings extending in the same direction. Even if a tension is applied in the lateral direction to correct the unevenness of the tension in the longitudinal direction, the tension does not act on the intervals between the slits, a uniform tension cannot be applied to the entire mask 103. However, a uniform tension can be applied even to a mask having a length substantially the same as that of one side of the glass substrate 105, as in this example, provided that the width is sufficiently smaller than the length.

Any method can be employed to fix the mask 103 to the mask frame 102 provided that the mask 103 does not come off the mask frame 102 or is not displaced from its fixed position. In this example, two short sides of the mask 103 were fixed to the mask frame 102 by resistance welding to manufacture the mask assembly 101. Ten mask assemblies 101 were manufactured.

The positional accuracies of the openings 301 of the manufactured mask assemblies 101 were evaluated using a 2D line-scale measuring machine SMIC-800 (manufactured by Sokkia). The maximum displacement in the x-coordinate position of the opening pattern from the design value was satisfactory 3 μm in the ten mask assemblies 101.

### EXAMPLE 2

The amounts and shapes of the deflection along the long sides of the masks 103 of the ten mask assemblies 101 manufactured in Example 1 were evaluated using the same 2D line-scale measuring machine SMIC-800 (manufactured by Sokkia). All the masks 103 exhibited deflected shapes of the thin plates supported at two sides, whose maximum deflection amount was 50 μm to 100 μm.

These mask assemblies 101 and the glass substrate 105 having a size of 365 mm×460 mm×0.5 mm were brought into contact with each other, as indicated by arrows 604 in FIG. 7, and the gap between the glass substrate 105 and the mask 103 was evaluated by using an LT9000 laser displacement meter manufactured by KEYENC, with the glass substrate 105 placed on each of the mask assemblies 101. All the mask assemblies 101 successfully showed a gap as small as a few μm.

### EXAMPLE 3

The glass substrate 105 having a width of 365 mm, a length of 460 mm, and a thickness of 0.5 mm and the evaporation source 107 were placed as in FIG. 9, an organic EL material was deposited on the entire surface of the glass substrate 105 at a time without moving the glass substrate 105 stepwise, and the film thickness distribution in the plane of the glass substrate 105 was evaluated.

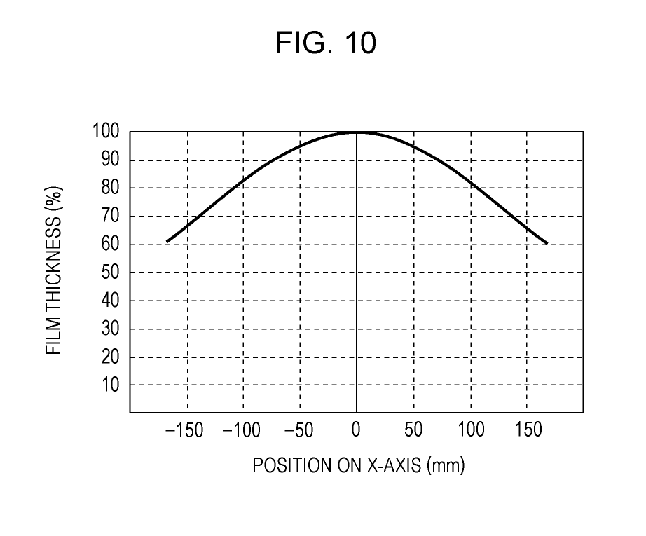

The evaporation source 107 was filled with 10.0 g Tris(8-hydroxyquinolinato)aluminum (hereinafter referred to as Alq3) as a deposition material. The Alq3 filled in the crucible of the evaporation source 107 was discharged through at least one opening of the evaporation source 107. The evaporation source 107 was placed directly below the center of the glass substrate 105 with the deposition surface down, and the distance from the center of the opening to the vapor deposition surface of the glass substrate 105 was set to 370 mm. Vapor deposition was performed to reach a thickness of 100 nm while monitoring the film thickness with a thickness sensor. After the vapor deposition, the deposited film was measured with an ellipsometer. The results are shown in FIG. 10.

FIG. 10 shows a film thickness distribution along the x-axis in FIG. 9. The vertical axis is normalized, with the thickness at the center of the glass substrate 105 (x=0) set to 100.

While the film thickness across a length of 400 mm in the lengthwise (x) direction of the glass substrate 105 ranged from 60 nm to 100 nm, the thickness distribution was ±2.0% in the range from 80 mm to 90 mm in width about the center (x=0) of the glass substrate 105. As a result, it was shown that setting the width of the deposition region when performing vapor deposition one column by one column within 90 mm provides a good thickness distribution within±2.0%.

### EXAMPLE 4

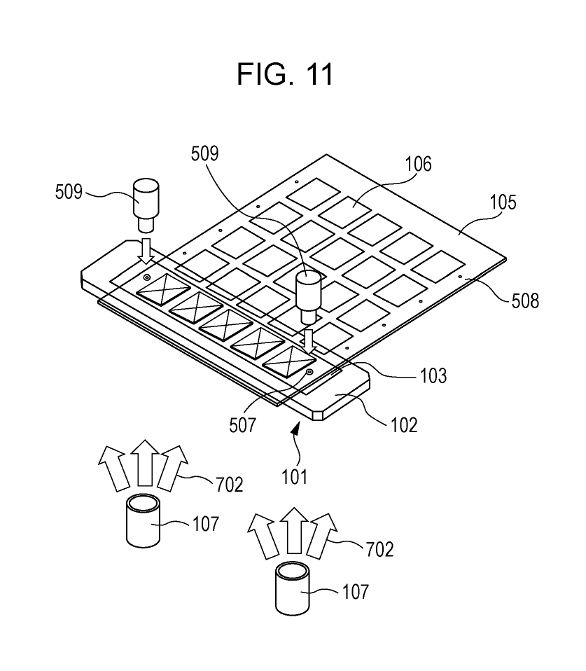

Vapor deposition was performed on the glass substrate 105 with the arrangement in FIG. 11 by using the mask assembly 101 manufactured in Example 1. Two evaporation sources 107 were placed in the longitudinal direction of the mask 103, and their positions were adjusted so that the film thickness distribution in the y-direction falls within±2.0%.

The evaporation sources 107 were filled with 10.0 g Tris(8-hydroxyquinolinato)aluminum (hereinafter referred to as Alq3) as a deposition material. The Alq3 filled in the crucibles of the evaporation sources 107 was evaporated through at least one opening of each evaporation source 107. The glass substrate 105 was placed on the opposite side of the evaporation sources 107, with the mask 103 therebetween, with the vapor deposition surface down. Evaporants 702 were discharged, with the evaporation sources 107 placed directly below the glass substrate 105. The distance from the center of the opening at the top of each evaporation source 107 to the vapor deposition surface of the glass substrate 105 was set to 370 mm. Vapor deposition was performed to reach a thickness of 100 nm while monitoring the film thickness with a thickness sensor.

The vapor deposition was performed for each of columns A to E, shown in FIG. 3, while moving the glass substrate 105 stepwise.

After the vapor deposition, a blur at the edge of the patterned deposited film on the glass substrate 105 was observed with a microscope or an atomic force microscope (AFM). The amount of misalignment between the deposition pattern and the electrode pattern was measured using a 2D line-scale measuring machine SMIC-800. Furthermore, a film thickness distribution in the entire pattern area of the glass substrate 105 was measured with an ellipsometer.

The measurement results showed that there is no blur at the edge of the deposited film and that the entire glass substrate 105 and the mask 103 are satisfactorily in close contact. Furthermore, the amount of misalignment with the electrode pattern was also favorably about 7 μm at the maximum. The film thickness distribution was also favorably within±2% across the entire glass substrate 105.

After completion of the vapor deposition, the other electrode was placed thereon and a protective film was further attached thereon, and the glass substrate 105 was divided into sections. Wiring cables for supplying power and inputting signals were attached to the divided glass substrate 105 to complete the organic EL display device. Also in the case where the number of divisions is large, vapor deposition is performed in the column direction in a lump, and hence a time proportional to the number of rows is sufficient to perform vapor deposition, thus allowing the organic EL display device to be manufactured in a short time.

Performing vapor deposition one column by one column as in the above examples can eliminate unevenness in film thickness among the columns. Furthermore, the area of vapor deposition can be smaller than that in a case where the entire surface is subjected to vapor deposition, thus allowing vapor deposition to be performed at a position with the highest deposition rate. Even if vapor deposition is performed without moving the evaporation source in the y-direction, the time for vapor deposition can be reduced as compared with the case of a moving deposition mode because the thickness distribution of the deposited film is small. Furthermore, since a uniform tension can be applied in the direction of the slits, a positional error of the openings in the direction perpendicular to the slits can be minimized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-175899 filed Aug. 11, 2011, which is hereby incorporated by reference herein in its entirety.

What is claimed is:

1. A method for manufacturing an EL device formed in each of a plurality of sections arrayed in matrix form on a substrate, the method comprising the step of:
depositing an evaporant onto the substrate through a mask held between the substrate and an evaporation source opposite the substrate, the mask having deposition patterns of all the sections in a column direction as openings,
wherein the step is repeated while moving the substrate in a row direction of the sections one column at a time.

2. The method for manufacturing an EL device according to claim 1, wherein the openings of the mask are a plurality of parallel slits extending in the column direction for each of the section.

3. The method for manufacturing an EL device according to claim 1, wherein the mask is held by applying a tension in the column direction.

4. The method for manufacturing an EL device according to claim 1, wherein the mask is held in close contact with or close vicinity to the substrate.

5. The method for manufacturing an EL device according to claim 1, wherein the substrate is supported horizontally by two sides parallel to the row direction.

6. The method for manufacturing an EL device according to claim 5, wherein the substrate is supported by support members provided for the individual columns.

7. The method for manufacturing an EL device according to claim 1, wherein the substrate and the mask are aligned every time the substrate is moved one column by one column in the row direction of the sections.

8. The method for manufacturing an EL device according to claim 7, wherein the substrate has alignment marks for the individual columns.

9. The method for manufacturing an EL device according to claim 1, further comprising the step of cutting the substrate into the sections after vapor deposition of all the sections is completed.

10. The method for manufacturing an EL device according to claim 1, wherein evaporants that emit different colors of light are deposited to different positions.

11. The method for manufacturing an EL device according to claim 1, wherein the evaporant includes an organic compound.

12. A vapor deposition method for forming deposition patterns in individual plurality of sections arrayed in matrix form on a substrate, the method comprising the step of:
depositing an evaporant onto the substrate through a mask held between the substrate and an evaporation source opposite the substrate, the mask having deposition patterns of all the sections in a column direction as openings,
wherein the step is repeated while moving the substrate in a row direction of the sections one column at a time.

13. A vapor deposition apparatus comprising:
an evaporation source;
a rectangular mask;
a mask frame that fixes the short sides of the rectangular mask and that holds the rectangular mask by applying a tension in a longitudinal direction;
a substrate supporting unit provided along the extensions of the two short sides of the rectangular mask and supporting a substrate whose length is larger than the short sides of the rectangular mask with opposing two sides of the substrate supporting unit;
a moving mechanism that moves the substrate supporting unit in the lengthwise direction of the substrate by a predetermined distance; and
an alignment unit that adjusts the relative position of the rectangular mask and the substrate.

14. The vapor deposition apparatus according to claim 13, wherein the substrate supporting unit horizontally supports the substrate with two sides parallel in the lengthwise direction.

15. The vapor deposition apparatus according to claim 14, wherein the substrate supporting unit includes support members provided for the individual columns.

16. The vapor deposition apparatus according to claim 13, wherein the evaporation source is provided at a plurality of locations along the long sides of the rectangular mask.
